(19) United States
(12) Patent Application Publication
(10) Pub. No.: US 2019/0051553 A1
(43) Pub. Date: Feb. 14, 2019

(54) Methods of Transferring a Graphene Monolayer via a Stacked Structure and Devices Fabricated Thereby

(71) Applicant: SPAWAR Systems Center Pacific, San Diego, CA (US)

(72) Inventors: Nackieb M. Kamin, Kapolei, HI (US); Marcio C. de Andrade, San Diego, CA (US); David Garmire, Honolulu, HI (US); Richard C. Ordonez, Mililani, HI (US)

(73) Assignee: United States of America as represented by Secretary of the Navy, San Diego, CA (US)

(21) Appl. No.: 15/674,852

(22) Filed: Aug. 11, 2017

(51) Int. Cl. H01L 21/683; H01L 21/02; H01L 21/78

(52) U.S. Cl. CPC H01L 21/6836; H01L 21/02527; H01L 21/02425; H01L 21/0262; H01L 21/7806; H01L 31/1804; H01L 21/02118; H01L 21/02282; H01L 2221/68318; H01L 2221/68363; H01L 2221/68381; H01L 21/02079

(57) ABSTRACT

A method of fabricating a graphene device generally involving depositing a graphene monolayer from a carbon source on a metal catalyst layer; depositing a transfer substrate on the graphene monolayer by way of casting, thereby forming a transfer-substrate/graphene/metal-catalyst structure; annealing the transfer-substrate/graphene/metal-catalyst structure, thereby forming an annealed transfer-substrate/graphene/metal-catalyst structure; coupling a thermal adhesive with the transfer-substrate/graphene/metal-catalyst structure; moving the annealed transfer-substrate/graphene/metal-catalyst structure to a target area of a target device, by using a probe assembly or the like, thereby forming an annealed transfer-substrate/graphene/metal-catalyst/thermal-adhesive/target-device structure; releasing the slip of thermal adhesive from the annealed transfer-substrate/graphene/metal-catalyst thermal-adhesive/target-device structure by applying heat, thereby forming an annealed transfer-substrate/graphene/metal-catalyst/target-device structure; etching away the metal catalyst layer from the annealed transfer-substrate/graphene/metal-catalyst/target-device structure in an etching solution, thereby forming a graphene/transfer-substrate/target-device structure; rinsing the graphene/transfer-substrate/target-device structure with DI water, thereby removing any excess etching solution; and drying the graphene/transfer-substrate/target-device structure, thereby providing the graphene device.

### FEDERALLY-SPONSORED RESEARCH AND DEVELOPMENT

The United States Government has ownership rights in the subject matter of the present disclosure. Licensing inquiries may be directed to Office of Research and Technical Applications, Space and Naval Warfare Systems Center, Pacific, Code 72120, San Diego, Calif., 92152; telephone (619) 553-5118; email: ssc_pac_t2@navy.mil. Reference Navy Case No. 102,799.

### BACKGROUND OF THE INVENTION

### Technical Field

The present disclosure technically relates to graphene structures. Particularly, the present disclosure technically relates to fabrication of graphene structures.

### Description of Related Art

In the related art, graphene is a two-dimensional layer of carbon atoms arranged in a honeycomb crystal lattice held together by strong Van der Waals forces. Graphene research has shown enormous potential in the areas of device physics and clean energy. However, due to an atomic thickness of only a single atom, traditional fabrication processes fail. An attempt has been made, in the related art, to anneal thermoplastics on a single layer of graphene synthesized on metal substrates followed by an exfoliation process to isolate graphene on flexible displays. However, as the metal catalyst is removed and the graphene absorbs the shape of the transfer substrate involved, the graphene experiences resistance changes as the elastic transfer substrate is stretched and deformed. The result is degradation of the electronic response of graphene. Also in the related art, an attempt to synthesize mono-layer graphene on integrated circuits has been made. However, the temperatures required for proper graphene synthesis tend to damage die substrates. Therefore, a need exists for a method of fabricating graphene devices that does not adversely affect electrical characteristics of graphene nor damage the fabrication tools, dies, or the like.

### SUMMARY OF INVENTION

To address at least the needs in the related art, the present disclosure generally involves a method of fabricating a graphene device, the method comprising: depositing a graphene monolayer from a carbon source on a metal catalyst layer by way of chemical vapor depositions (CVD), thereby forming a graphene/metal structure; depositing a transfer substrate, such as acrylics, polyimide films, polymers, and or plastics, on the graphene monolayer by way of casting, thereby forming a transfer-substrate/graphene/metal-catalyst structure; annealing the transfer-substrate/graphene/metal-catalyst structure, thereby forming a protective barrier and an isolation layer by way of the transfer substrate, thereby forming an annealed transfer-substrate/graphene/metal-catalyst structure; coupling a thermal adhesive with the transfer-substrate/graphene/metal-catalyst structure; moving the annealed transfer-substrate/graphene/metal-catalyst structure to a target area of a target device, by using a probe assembly or the like, thereby forming an annealed transfer-substrate/graphene/metal-catalyst/thermal-adhesive/target-device structure; releasing the slip of thermal adhesive from the annealed transfer-substrate/graphene/metal-catalyst thermal-adhesive/target-device structure by applying heat, thereby forming an annealed transfer-substrate/graphene/metal-catalyst/target-device structure; etching away the metal catalyst layer from the annealed transfer-substrate/graphene/metal-catalyst/target-device structure in an etching solution, thereby forming a graphene/transfer-substrate/target-device structure; rinsing the graphene/transfer-substrate/target-device structure with DI water, thereby removing any excess etching solution; and drying the graphene/transfer-substrate/target-device structure, thereby providing the graphene device.

### BRIEF DESCRIPTION OF THE DRAWINGS

The above, and other, aspects, features, and benefits of several embodiments of the present disclosure are further understood from the following Detailed Description of the Invention as presented in conjunction with the following drawings.

FIG. 1A is a diagram illustrating a precursor material for forming a substrate, such as an elastomeric silicone substrate kit comprising a silicone base and a curing agent, for synthesizing polydimethlysiloxane (PDMS), by example only, for use in fabricating a graphene device, in accordance with embodiments of the present disclosure.

FIG. 1B, is a diagram illustrating the chemical structure of a precursor material for use in forming a substrate, in accordance with an embodiment of the present disclosure.

FIG. 2 is a diagram illustrating deposition or depositing, by spin coating, a material, such as PDMS, on a graphene/metal-catalyst structure, using a spin coater, thereby providing a transfer substrate/graphene/metal-catalyst structure, in accordance with embodiments of the present disclosure.

FIG. 3 is a diagram illustrating a probe assembly for use in fabricating a graphene device, in accordance with embodiments of the present disclosure.

FIG. 4 is a diagram illustrating transferring a PDMS/graphene/Cu structure to a semiconductor substrate, such as a complementary metal-oxide-semiconductor (CMOS) die, in accordance with embodiments of the present disclosure.

FIG. 5 is a diagram illustrating a chemical structure for ammonium persulfate (APS), e.g., in a crystalline form, for use in fabricating a graphene device, in accordance with embodiments of the present disclosure.

FIG. 6 is a graphic diagram illustrating a sample to be etched on a 3D printed etching platform, in accordance with embodiments of the present disclosure.

FIG. 7A is a flow diagram illustrating a method of fabricating a graphene device by transferring a graphene monolayer via a stacked structure, in accordance with embodiments of the present disclosure.

FIG. 7B is a flow diagram illustrating a method of fabricating a graphene device by transferring a graphene monolayer via a stacked structure, in accordance with embodiments of the present disclosure.

FIG. 7C is diagram illustrating a general workflow for fabricating a graphene device, in accordance with an embodiment of the present disclosure.

FIG. 8 is a diagram illustrating a graphene device fabricated by a method of transferring a graphene monolayer on a stacked structure, such as by the workflow, as shown in FIG. 7C, in accordance with embodiments of the present disclosure.

Corresponding reference numerals or characters indicate corresponding components throughout the drawings. Elements in the several figures are illustrated for simplicity and clarity and have not necessarily been drawn to scale. For example, the dimensions of some of the elements in the figures may be emphasized relative to other elements for facilitating understanding of the various presently disclosed embodiments. Also, common, but well-understood, elements that are useful or necessary in commercially feasible embodiment are often not depicted in order to facilitate a less obstructed view of these various embodiments of the present disclosure.

### DETAILED DESCRIPTION OF THE EMBODIMENT(S)

The present disclosure encompasses a method of preparing and transferring a graphene monolayer onto a stacked structure, wherein the graphene monolayer comprises a single layer of carbon atoms responsive to the presence of adsorbates for facilitating sensing thereof. The graphene monolayer has linear energy dispersion and two-dimensional structure properties which facilitate its use in nanoscale applications and in atomic level charge particle detection via charge detection on a surface of the graphene monolayer. In accordance with some embodiments of present disclosure, the method of preparing and transferring a graphene monolayer onto a stacked structure alternatively involves using an additive manufacturing technique, such as using a 3D printed platform. Graphene is synthesized on a metal catalyst layer, such as at least one of copper (e.g., a copper film), boron nitride, and nickel, by way of a chemical vapor deposition (CVD) from a carbon source. The embodiments of the present disclosure may be used for electronic applications in the military, medical, and aerospace fields. The embodiments of the present disclosure provide non-contact, non-volatile, fabrication methods of transferring a single layer of graphene to an electronic platform, such as a semiconductor device or an integrated circuit, whereby strain on the single layer of graphene is minimized.

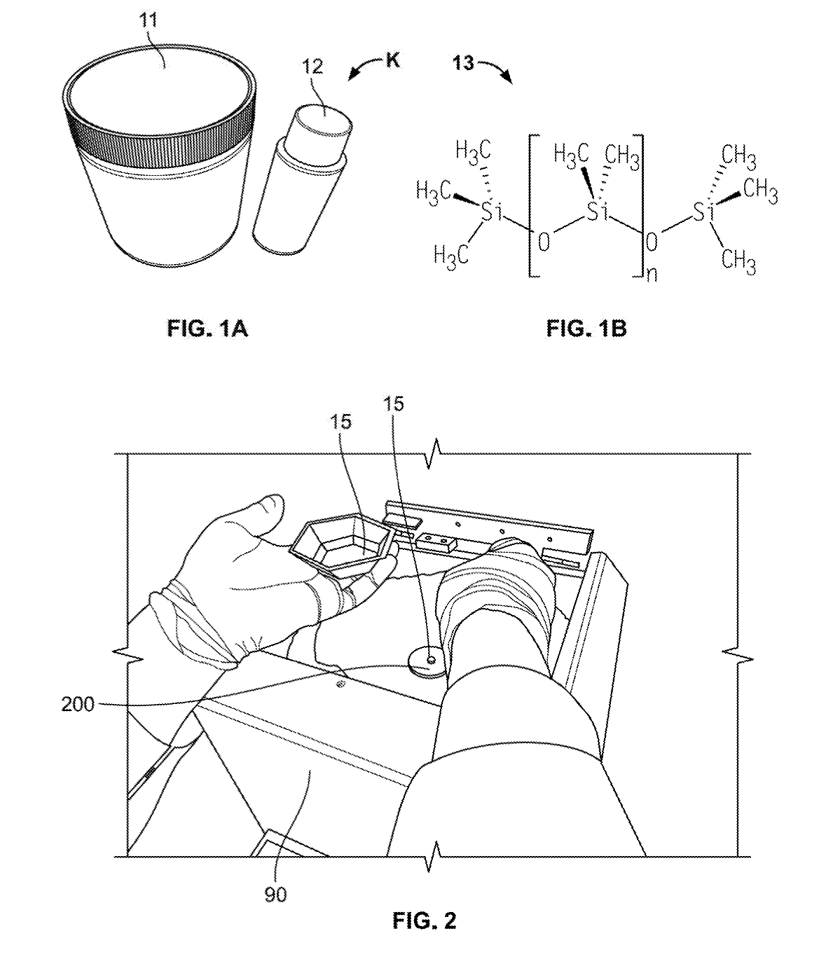

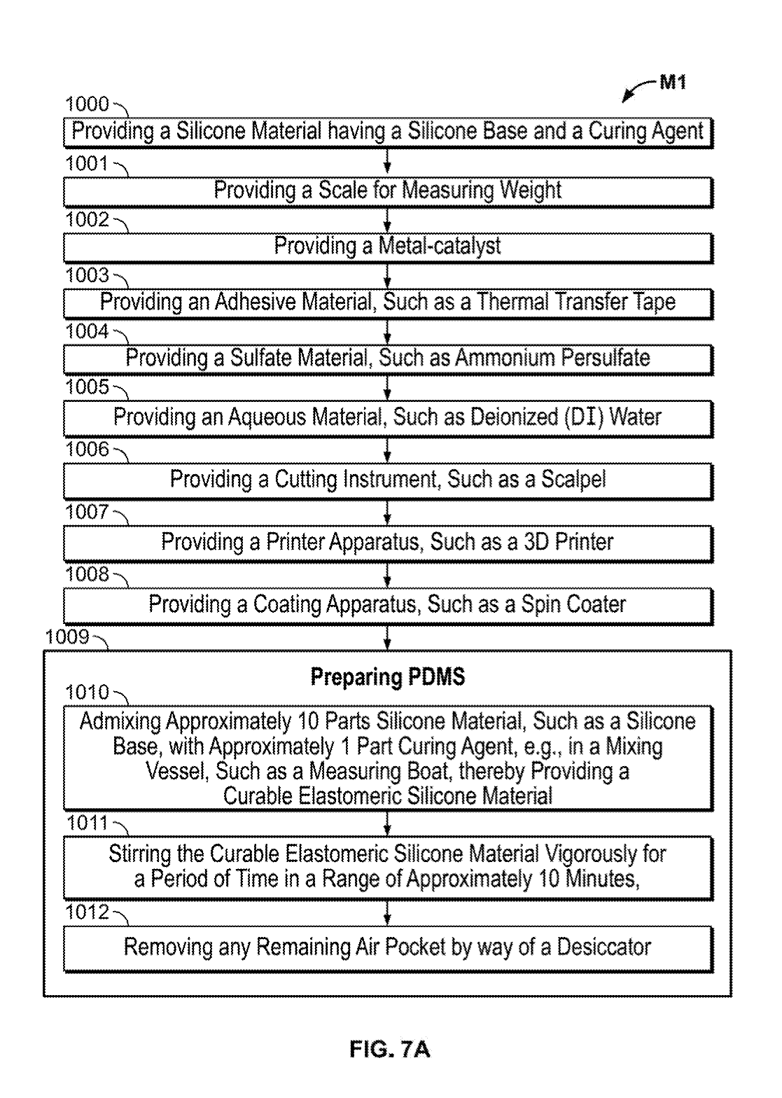

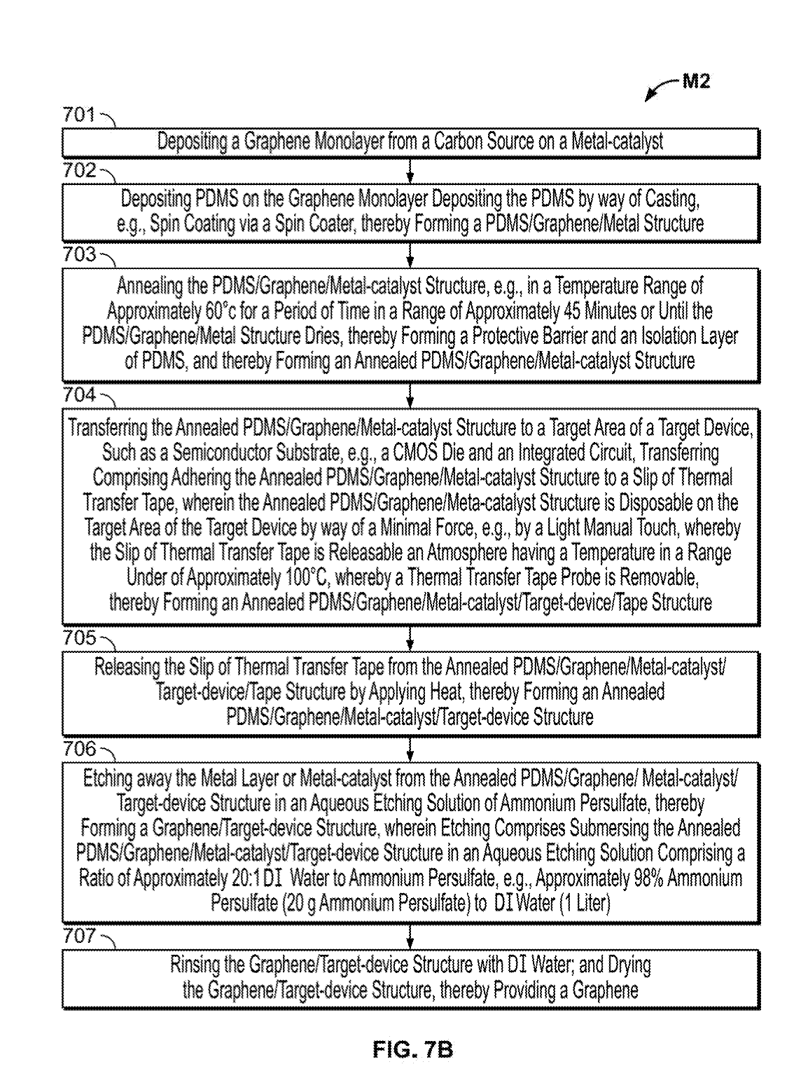

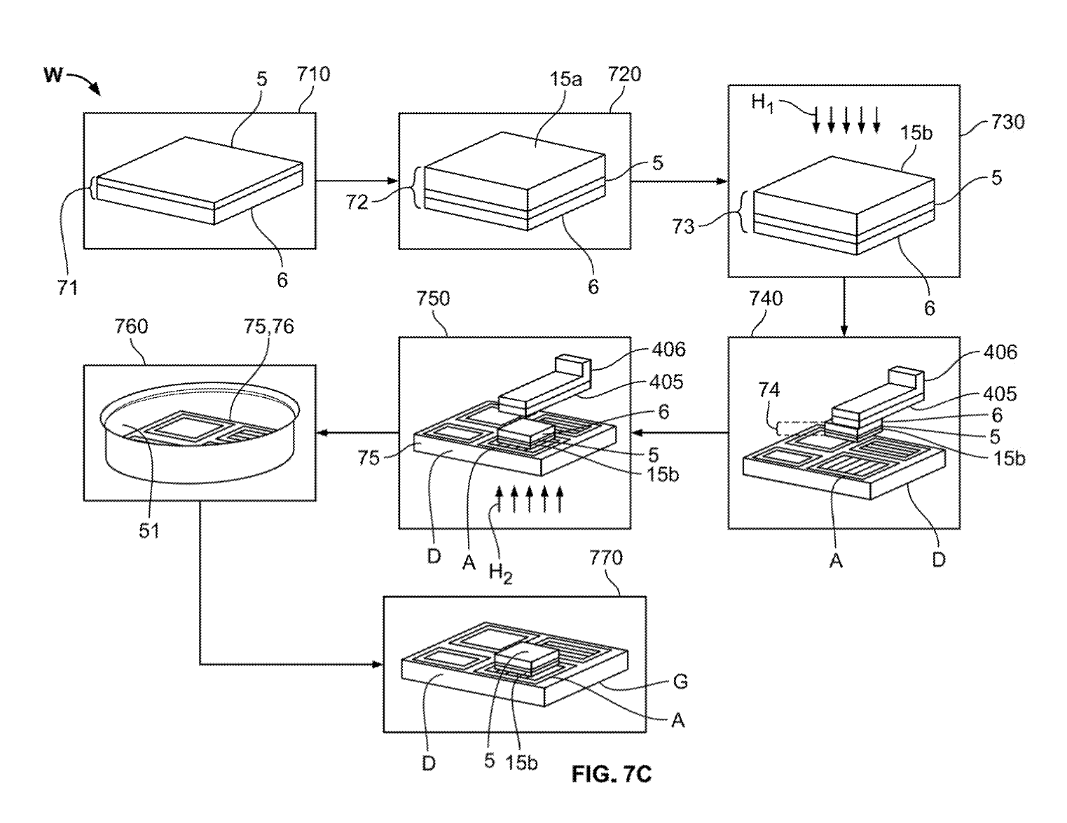

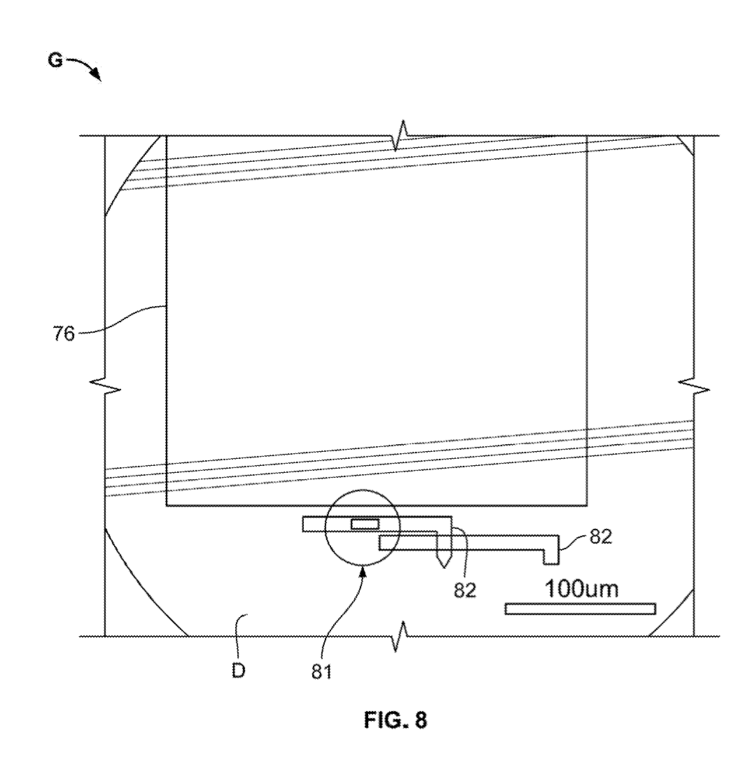

Referring to FIG. 1A, this diagram shows a precursor material, such as a silicone material formable via an elastomeric silicone material kit K comprising a silicone base 11 and a curing agent 12. The curing agent 12 may be a silicone elastomer kit for use in synthesizing or forming a transfer substrate 15b, such as comprising a PDMS layer 15a, by example only. The kit K may be used for fabricating a graphene device G (FIGS. 7C and 8), in accordance with an embodiment of the present disclosure. Alternative precursor materials can be utilized to synthesize other polymeric substrates, such as acrylics, polyimide films, and a variety of plastics. By example only, the precursor material used for synthesizing or forming a transfer substrate 15b (FIG. 7C) is PDMS; however, the substrate may comprise any number of materials, e.g., other polymeric materials, inorganic materials, etc.

Referring to FIG. 1B, this diagram illustrates the chemical structure 13 of a precursor material having the formula CH₃[Si(CH₃)₂O]ₙSi(CH₃)₃, wherein n is the number of repeating monomer [SiO(CH₃)₂] units), by example only, in accordance with an embodiment of the present disclosure.

Referring to FIG. 2 and referring ahead to FIGS. 4 and 7B, this diagram illustrates a step of depositing the PDMS 15, e.g., having a thickness in a range of approximately 10 microns. The PDMS 15 may be deposited on a graphene/metal-catalyst structure 200. One way such deposition may occur is by a CVD process, by spin coating via a spin coater or coating apparatus 90, in the method M1 (FIG. 7A). A PDMS/graphene/metal-catalyst structure (not shown) is thereby provided, in accordance with embodiments of the present disclosure. A volume of the PDMS 15, e.g., a droplet of the PDMS 15, is disposed, e.g., via a pipette (not shown), on the graphene/metal-catalyst structure 200 (coupled with a chuck). The chuck (not shown) is spun by a motor (not shown) of the spin coater 90, whereby the graphene/metal-catalyst structure 200 is spun-coat with a layer of the PDMS 15 via centripetal acceleration. The method M2 further comprises heating the PDMS/graphene/metal-catalyst structure, e.g., in an oven, in a temperature range of approximately 60° C. for a period of time in a range of approximately 45 minutes or until the PDMS/graphene/metal-catalyst structure becomes dry (not shown). A protective barrier and an isolation layer is thereby formed, comprising the PDMS 15 The PDMS/graphene/metal-catalyst structure PDMS is compatible with a target device D (FIG. 8), such as an electronic platform. Examples of electronic platforms include, but are not limited to, a semiconductor substrate, a CMOS die, and an integrated circuit (IC) device. The method M2 further comprises cutting the PDMS/graphene/metal-catalyst structure 300 to a desirable size by way of the cutting instrument (not shown).

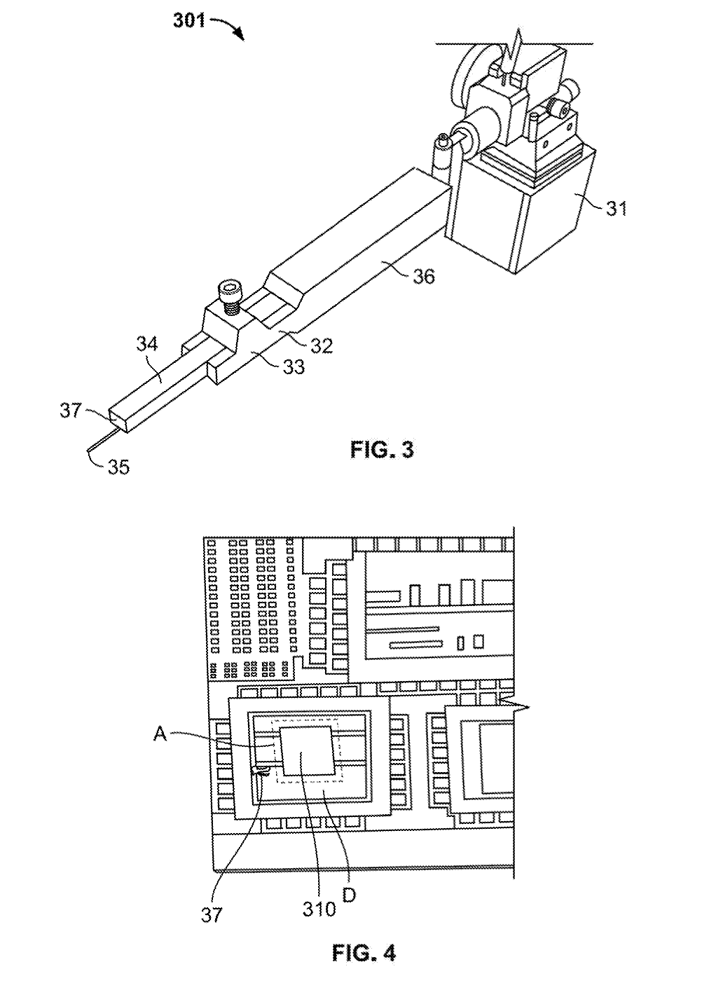

Referring to FIG. 3, this diagram illustrates a probe assembly 301 for use in fabricating a graphene device G, e.g., in the method M1 (FIG. 7A), the method M2 (FIG. 7B), or the workflow W (FIG. 7C), in accordance with embodiments of the present disclosure. The probe assembly 301 comprises a micro-manipulator stage 31, such as an XYZ translation probe stage, a probe holder 32 having a shaft 36, an extender attachment 33, a thermal transfer probe 34, and a thermal adhesive probe tip 35, by example only. The thermal transfer probe 34 is coupled with the thermal adhesive probe tip 35. At least one of the probe holder 32, the extender attachment 33, the thermal transfer probe 34, the thermal adhesive probe tip 35, and the slip of thermal adhesive 37, is formed by 3D printing.

Referring to FIG. 4, this diagram illustrates a step of transferring a PDMS/graphene/metal-catalyst structure (not shown) to a target device D, in accordance with embodiments of the present disclosure. The method M2 (FIG. 7B) further comprises transferring the PDMS/graphene/metal-catalyst structure (not shown) in relation to a target device D. Examples of target devices include, but are not limited to, a semiconductor substrate, a CMOS device, and an IC, by example only. Now referring to FIGS. 3 and 4 together, the thermal transfer probe 34 of the probe assembly 301 is configured to dispose the PDMS/graphene/metal-catalyst structure (not shown) in relation to the target device D via actuation by the micro-manipulator stage 31, for accurate placement and alignment with the target device D. The thermal adhesive probe tip 35 is configured to contact a surface of the metal-catalyst portion of the PDMS/graphene/metal-catalyst structure (not shown). Thereby, any strain on the graphene monolayer 5 (FIG. 8) is reducible while transferring the PDMS/graphene/metal-catalyst structure (not shown) in relation to the target device D. Once the metal-catalyst portion of the structure (not shown) adheres to the slip of thermal adhesive 37, the PDMS/graphene/metal-catalyst structure (not shown) is disposable on a target area A of the target device D by way of a minimal force, thereby forming a PDMS/graphene/metal-catalyst/thermal-adhesive structure 310. The slip of thermal adhesive 37 is then releasable in an atmosphere having a temperature in a range under approximately 100° C. The thermal adhesive probe 34 is thereby removable, e.g., by actuation of the micro-manipulator stage 31, thereby forming a PDMS/graphene/metal-catalyst/target-device structure 320 (FIG. 6).

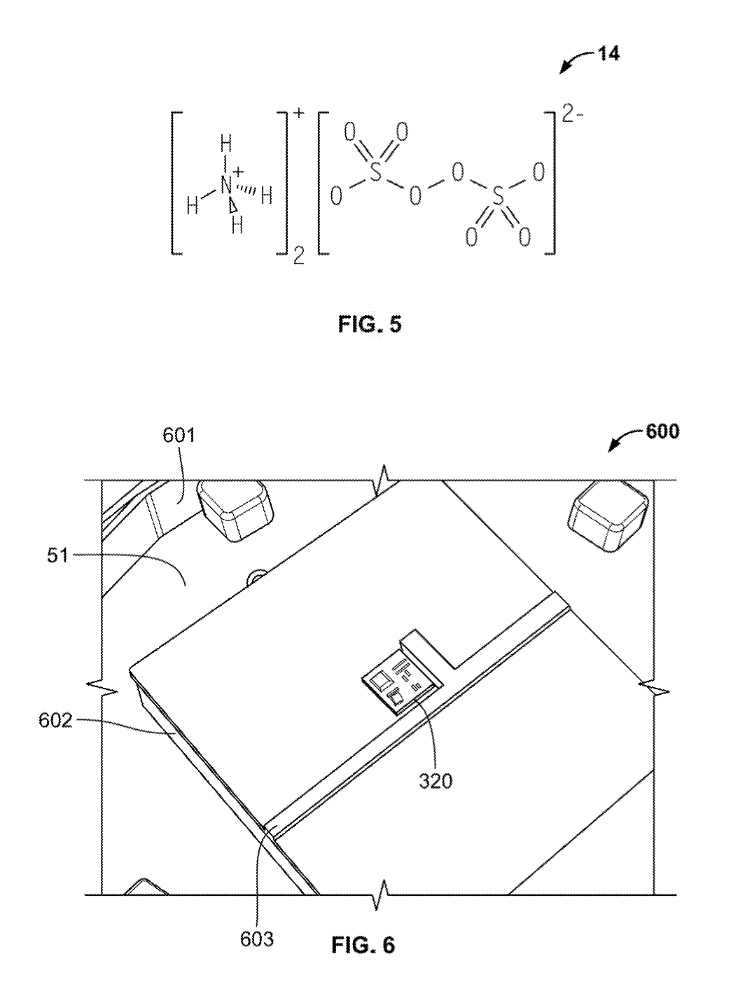

Referring to FIG. 5, this diagram illustrates a chemical structure 14 for use as an etching material or etchant (not shown), such as APS, used in an etching solution 51 for use in fabricating a graphene device G (FIG. 8), in accordance with an embodiment of the present disclosure. The APS may be in a crystalline form.

Still referring to FIG. 5 and ahead to FIGS. 7B and 7C, the method M2 (FIG. 7B) further comprises etching away the metal catalyst layer 6, e.g., a copper portion, of the PDMS/graphene/metal-catalyst/thermal-adhesive structure 310 (FIG. 4) by submersing the PDMS/graphene/metal-catalyst/target-device structure 320 (FIG. 6) in an etching solution 51 (FIG. 6) comprising a ratio of approximately 20:1 DI water to APS, e.g., approximately 98% APS (approximately 20 grams APS) to DI water (approximately 1 liter), by example only. APS is the inorganic compound with the formula (NH₄)₂S₂O₈, by example only, and is a colorless (white) salt that is highly soluble in water. APS is a strong oxidizing agent for use in polymer chemistry. APS may be used as an etchant, e.g., as used in the etching solution 51. APS may also be used as a cleaning and bleaching agent. The dissolution of APS in water is an endothermic process.

Referring to FIG. 6, this diagram illustrates a sample to be etched on an angled etching platform 600, such as a 3D printed etching platform by example, in accordance with embodiments of the present disclosure. The etching step of the method M2 (FIG. 7B) further comprises using an angled etching platform 600 for increasing the reactivity of the copper portion of the PDMS/graphene/metal-catalyst/target-device structure 320 and the etching solution 51. A PDMS/graphene/target-device structure (not shown) is thereby formed. The angled etching platform 600 comprises a 3D printed bowl 601 having a platform 602 disposed at an angle of approximately 15°. The platform 602 comprises a 2-mm ledge 603 for facilitating retention of the PDMS/graphene/metal-catalyst/target-device structure 320. The 3D printed bowl 601 is vertically extruded to accommodate a necessary or desired volume of etching solution 51. The method M1 further comprises rinsing the PDMS/graphene/metal-catalyst/target-device structure 320 with DI water (not shown), thereby providing the graphene device G (FIG. 8). The method M1 further comprises drying the device G (FIG. 8) by applying heat thereto in an oven, the device comprising the graphene monolayer 5 (FIG. 8) transferred in relation to the target device D (FIG. 8).

Referring to FIG. 7A this flow diagram illustrates a method M1 of fabricating a graphene device G (FIG. 8), by transferring a graphene monolayer 5 (FIG. 8) via a stacked structure, comprising: providing a transfer substrate 15b, providing the transfer substrate 15b comprising providing a precursor material having a silicone base 11 (FIG. 1A) and a curing agent 12 (FIG. 1A), such as a silicone elastomer kit K (FIG. 1A), as indicated by block 1000. The method M1 also comprises providing a scale (not shown) for measuring weight, as indicated by block 1001. The method M1 still further comprises providing a graphene-and-copper (graphene/Cu) sample (not shown), such as a graphene platform, as indicated by block 1002. The method M1 yet further comprises providing an adhesive material (not shown), such as a thermal adhesive, as indicated by block 1003, and providing a sulfate material (not shown), such as ammonium persulfate, e.g., (NH₄)₂S₂O₈, as indicated by block 1004. Additional steps in the method M1 comprise providing an aqueous material (not shown), such as deionized (DI) water, as indicated by block 1005, and providing a cutting instrument (not shown), such as a scalpel, as indicated by block 1006. The method M1 also comprises providing a printer apparatus (not shown), such as a 3D printer, as indicated by block 1007, and providing a coating apparatus 90 (FIG. 2), such as a spin coater, as indicated by block 1008, in accordance with an embodiment of present disclosure.

Still referring to FIG. 7A and referring back to FIGS. 1A and 2, together, the method M1 further comprises preparing PDMS 15, as indicated by block 1009. Preparing PDMS 15 comprises admixing approximately 10 parts silicone precursor material, such as a silicone base 11 (FIG. 1A), with approximately 1 part curing agent 12 (FIG. 1A). These elements may be admixed in a mixing vessel (not shown), such as a measuring boat (not shown), thereby providing a curable elastomeric silicone material (not shown) as indicated by block 1010. The method M1 also comprises stirring the curable elastomeric silicone material (not shown) vigorously for a period of time in a range of approximately 10 minutes, thereby facilitating even distribution of the curing agent 12, as indicated by block 1011, and removing any remaining air pocket (not shown) by way of a desiccator (not shown), thereby providing the PDMS 15, as indicated by block 1012.

Referring to FIG. 7B, this flow diagram illustrates a method M2 of fabricating a graphene device G by transferring a graphene monolayer 5 (FIG. 8) via a stacked structure, in accordance with an embodiment of the present disclosure. The method M2 involves a non-contact graphene transfer process for integrating graphene, such as a graphene monolayer, with electronic devices, such as integrated circuits. By using the method M2, a developer can transfer graphene to small target areas with minimum surface strain. The method M2 is performable in a laboratory environment. The method M2 is scalable for larger manufacturing operations of graphene integrated devices.

Still referring to FIG. 7B, referring back to FIG. 2, and referring ahead to FIG. 7C, the method M2 comprises: depositing a graphene monolayer 5 (FIG. 7C) from a carbon source on a metal catalyst or a metal catalyst layer 6 (FIG. 7C), such as at least one of copper, (e.g., a copper film), boron nitride, and nickel, by way of CVD, thereby forming a graphene/metal-catalyst structure 71 (FIG. 7C), as indicated by block 701; depositing PDMS 15 (FIG. 2) on the graphene monolayer 5, e.g., by way of casting, such as spin-coating via a spin coater, thereby providing a PDMS layer 15a, and thereby forming a PDMS/graphene/metal-catalyst structure 72 (FIG. 7C), as indicated by block 702; annealing the PDMS/graphene/metal-catalyst structure 72 (FIG. 7C), e.g., in a temperature range of approximately 60° C. for a period of time in a range of approximately 45 minutes or until the PDMS/graphene/metal-catalyst structure 72 (FIG. 7C) dries, thereby forming a protective barrier and an isolation layer by way of the PDMS layer 15a, and thereby forming an annealed PDMS/graphene/metal-catalyst structure 73, wherein the PDMS layer 15a becomes a PDMS substrate 15b, as indicated by block 703; transferring the annealed PDMS/graphene/metal-catalyst structure 73 (FIG. 7C) to a target area A of a target device D, such as a semiconductor substrate, e.g., a CMOS die and an integrated circuit, transferring comprising adhering the annealed PDMS/graphene/metal-catalyst structure 73 (FIG. 7C) to a slip of thermal adhesive 405 (FIG. 7C), wherein the annealed PDMS/graphene/meta-catalyst structure 73 (FIG. 7C) is disposable on the target area A of the target device D by way of a minimal force, e.g., by a light manual touch, whereby the slip of thermal adhesive 405 (FIG. 7C) is releasable in an atmosphere having a temperature in a range under of approximately 100° C., whereby a thermal adhesive probe 406 is removable, thereby forming an annealed PDMS/graphene/metal-catalyst/target-device/thermal-adhesive structure 74 (FIG. 7C), as indicated by block 704; releasing the slip of thermal adhesive 405 (FIG. 7C) from the annealed PDMS/graphene/metal-catalyst/target-device/thermal-adhesive structure 74 (FIG. 7C) by applying heat, thereby forming an annealed PDMS/graphene/metal-catalyst/target-device structure 75 (FIG. 7C), as indicated by block 705; etching away the metal catalyst layer 6 (FIG. 7C) from the annealed PDMS/graphene/metal-catalyst/target-device structure 75 (FIG. 7C) in an aqueous etching solution 51 of APS, thereby forming a graphene/target-device structure 76 (FIG. 7C), wherein etching comprises submersing the annealed PDMS/graphene/metal-catalyst/target-device structure 75 (FIG. 7C) in an aqueous etching solution 51 (FIG. 7C) comprising a ratio of approximately 20:1 DI water to APS, e.g., approximately 98% APS (20 g APS) to DI water (1 liter), as indicated by block 706; rinsing the graphene/target-device structure 76 (FIG. 7C) with DI water; and drying the graphene/target-device structure 76 (FIG. 7C), thereby providing a graphene device G (FIGS. 7C and 8), as indicated by block 707, in accordance with an embodiment of the present disclosure.

Referring to FIG. 7C, this diagram illustrates a general workflow W for fabricating a graphene device G, comprising: depositing, e.g., via CVD, a graphene monolayer 5 on a metal catalyst layer 6, such as a copper (Cu) foil, thereby forming a graphene/metal-catalyst structure 71, as indicated by block 710; casting, e.g., via spin-coating, PDMS 15 on the graphene monolayer 5 of the graphene/metal-catalyst structure 71, thereby forming a PDMS/graphene/metal-catalyst structure 72, as indicated by block 720; annealing, e.g., via applying heat H₁, the PDMS/graphene/metal-catalyst structure 72, thereby forming annealed PDMS/graphene/metal-catalyst structure 73, as indicated by block 730; transferring, e.g., via a transfer structure 406, the annealed PDMS/graphene/metal-catalyst structure 73 to a target area A of a target device D, such as a semiconductor substrate, e.g., a CMOS die and an integrated circuit, transferring comprising applying a thermal adhesive 405, e.g., a thermally releasable tape, to the metal catalyst layer 6 of the annealed PDMS/graphene/metal-catalyst structure 73, disposing the annealed PDMS/graphene/meta-catalyst structure 73 over the target area A of the target device D, wherein the PDMS layer 15 faces the target device D, as indicated by block 740; releasing the thermal adhesive 405 from the annealed PDMS/graphene/meta-catalyst structure 73 by applying heat H₂, thereby forming an annealed metal-catalyst/graphene/PDMS/target-device structure 75, as indicated by block 750; etching away the metal catalyst layer 6 from the annealed metal-catalyst/graphene/PDMS/target-device structure 75, e.g., in an aqueous etching solution 51 of APS, thereby forming a graphene/PDMS/target-device structure 76, wherein etching comprises submersing the annealed PDMS/graphene/metal-catalyst/target-device structure 75 in an aqueous etching solution 51 comprising a ratio of approximately 20:1 DI water to APS, e.g., approximately 98% APS (20 g APS) to DI water (1 liter), as indicated by block 760; rinsing the graphene/PDMS/target-device structure 76 with DI water; and drying the graphene/PDMS/target-device structure 76, thereby providing a graphene device G, as indicated by block 770, in accordance with an embodiment of the present disclosure.

Referring to FIG. 8, this diagram illustrates a graphene device G fabricated by the method M2, as shown in FIG. 7B or the workflow W, as shown in FIG. 7C, of transferring a cast PDMS layer 15 on a graphene monolayer 5 to an integrated circuit (IC), in accordance with an embodiment of the present disclosure. The graphene device G comprises: a target-device D; and a graphene monolayer 5 on the substrate 15b, the substrate 15b comprising the PDMS layer 15a, disposed on, and coupled with, the target-device D. In this example, the target-device D comprises the integrated circuit, the integrated circuit comprising a differential amplifier 81 coupled with a plurality of sense rails 82, wherein exposure of a surface of the graphene monolayer 5 to electromagnetic radiation triggers generation of a measurable electron-hole pair in the graphene monolayer 5.

It is understood that many additional changes in the details, materials, substrates, steps and arrangement of parts, which have been herein described and illustrated to explain the nature of the invention, may be made by those skilled in the art within the principle and scope of the invention as expressed in the appended claims.

What is claimed:

1. A method of fabricating a graphene device, the method comprising:
depositing a graphene monolayer from a carbon source on a metal-catalyst layer by way of chemical vapor deposition;
depositing a transfer-substrate on the graphene monolayer by way of casting;
annealing the transfer-substrate/graphene/metal-catalyst structure;
coupling a thermal adhesive with the transfer-substrate/graphene/metal-catalyst structure;
moving the transfer-substrate/graphene/metal-catalyst structure to a target area of a target-device;
releasing the thermal-adhesive from the transfer-substrate/graphene/metal-catalyst/thermal-adhesive/target-device structure by applying heat;
etching away the metal-catalyst layer from the transfer-substrate/graphene/metal-catalyst/target-device structure;
rinsing the graphene/transfer-substrate/target-device structure with deionized water; and
drying the graphene/transfer-substrate/target-device structure.

2. The method of claim 1, wherein the metal-catalyst layer comprises at least one of copper, a copper film, boron nitride, and nickel.

3. The method of claim 1, wherein casting is accomplished by spin-coating.

4. The method of claim 1, wherein releasing is accomplished by heating the annealed transfer-substrate/graphene/metal-catalyst structure at a temperature of under 100° C.

5. The method of claim 1, wherein transferring comprises providing the target device comprising at least one of a semiconductor substrate, a CMOS die, and an integrated circuit.

6. The method of claim 1, wherein etching is accomplished by submersing the graphene/metal-catalyst/target-device structure in an etching solution.

7. The method of claim 1, wherein etching is accomplished by the use of a solution having an etchant in deionized water.

8. The method of claim 7,
wherein the etchant to deionized water is in a mole ratio of approximately 20:1.

9. A graphene device fabricated by a method comprising:
depositing a graphene monolayer from a carbon source on a metal-catalyst layer by way of chemical vapor deposition;
depositing a substrate on the graphene monolayer by way of casting;
annealing the transfer-substrate/graphene/metal-catalyst structure;
coupling a thermal adhesive with the transfer-substrate/graphene/metal-catalyst structure;
moving the annealed transfer-substrate/graphene/metal-catalyst structure to a target area of a target device;
releasing the thermal adhesive from the annealed transfer-substrate/graphene/metal-catalyst structure by applying heat;
etching away the metal-catalyst layer from the annealed transfer-substrate/graphene/metal-catalyst/target-device structure;
rinsing the graphene/transfer-substrate/target-device structure; and
drying the graphene/transfer-substrate/target-device structure.

10. The graphene device of claim 9, wherein the metal catalyst layer comprises at least one of copper, a copper film, boron nitride, and nickel.

11. The graphene device of claim 9, wherein casting is accomplished by spin-coating.

12. The graphene device of claim 9,
wherein annealing comprises heating the transfer substrate/graphene/metal-catalyst structure to a temperature in the range of approximately 40-100° C. for approximately 45 minutes.

13. The graphene device of claim 9, wherein releasing is accomplished by heating the graphene/metal-catalyst structure to a temperature under approximately 100° C.

14. The graphene device of claim 9, wherein etching is accomplished via a wet etching process.

15. The graphene device of claim 14,
wherein the etching solution is comprised an etchant and deionized water.

16. The graphene device of claim 15, wherein the etching solution
a mole ratio of etchant to deionized water of approximately 20:1.
